(19) United States
(12) Patent Application Publication
(10) Pub. No.: US 2017/0125373 A1
(43) Pub. Date: May 4, 2017

(54) METHOD FOR PRODUCING SEMICONDUCTOR PACKAGE

(71) Applicant: NITTO DENKO CORPORATION

(72) Inventors: Kosuke Morita, Ibaraki-shi, Osaka (JP); Tsuyoshi Ishizaka, Ibaraki-shi, Osaka (JP); Jun Ishii, Ibaraki-shi, Osaka (JP); Goji Shiga, Ibaraki-shi, Osaka (JP); Chie Iino, Ibaraki-shi, Osaka (JP)

(21) Appl. No.: 15/107,222

(22) PCT Filed: Dec. 22, 2014
(86) PCT No.: PCT/JP2014/083906

§ 371 Date: Jun. 22, 2016

(30) Foreign Application Priority Data
Dec. 26, 2013 (JP) 2013-270073

(51) Int. Cl. H01L 23/00; H01L 21/78; H01L 21/56

(52) U.S. Cl. CPC H01L 24/96; H01L 21/561; H01L 21/568; H01L 21/78

(57) ABSTRACT

Provided is a method for producing a semiconductor package. By this method, a periphery of a light-exposure planning region can be prevented from being exposed to light. The method is a semiconductor package producing method in which a film-formation planning surface of a cured product has a surface roughness of a predetermined value or less.

### TECHNICAL FIELD

The present invention relates to a method for producing a semiconductor package.

### BACKGROUND ART

When semiconductor chips are sealed, a thermosetting resin sheet may be used (see, for example, Patent Document 1).

### PRIOR ART DOCUMENT

### Patent Document

Patent Document 1: JP-A-2013-7028

### SUMMARY OF THE INVENTION

### Problems to Be Solved By the Invention

When a semiconductor package is produced, the following process may be performed: a process of covering semiconductor chips fixed temporarily on a temporarily-fixing material with a sealing resin to form a sealed resin body; curing the resin region of the sealed resin body to form a cured resin body; and then forming a re-interconnection layer onto the cured resin body. When the re-interconnection layer is formed, a photosensitive buffer coat film is formed onto the cured resin body and openings are next made in the buffer coat film by photolithography.

When light-exposure planning regions of the buffer coat film are exposed to light, not only the light-exposure planning regions but also respective peripheries thereof may be exposed to light so that openings low in precision may be made.

An object of the present invention is to solve this problem and provide a method for producing a semiconductor package by which a periphery of a light-exposure planning region of a buffer coat film can be prevented from being exposed to light.

### Means for Solving the Problems

The present invention relates to a method for producing a semiconductor package, the method comprising:

a step of forming a sealed body by pressurizing a chip-temporarily-fixed body comprising a supporting plate, a temporarily-fixing material stacked over the supporting plate and a semiconductor chip fixed temporarily over the temporarily-fixing material, and a thermosetting resin sheet arranged over the chip temporarily-fixed body,
the sealed body comprising the semiconductor chip and the thermosetting resin sheet covering the semiconductor chip;

a step of forming a cured body by heating the sealed body to cure the thermosetting resin sheet,
the cured body comprising the semiconductor chip and a resultant cured resin covering the semiconductor chip;

a step of peeling off the temporarily-fixing material from the cured body; and

a step of forming a re-interconnection body by forming a re-interconnection layer over a surface of the cured body that had contacted the temporarily-fixing material.

The step of forming the re-interconnection body comprises: a step of forming a photosensitive buffer coat film over the surface of the cured body that had contacted the temporarily-fixing material, and a step of making an opening in the buffer coat film by subjecting a workpiece to exposure to light and development. In the surface of the cured body that contacts the temporarily-fixing material, the cured resin has a surface roughness of 3000 nm or less.

In the present invention, the surface of the cured body that contacts the temporarily-fixing material (hereinafter, the surface may be referred to as the film-formation planning surface) is small in surface roughness; accordingly, when the light for the exposure is radiated onto the buffer coat film, the exposure light is restrained from being irregularly reflected on the film-formation planning surface. The restraint makes it possible to prevent any periphery of the light-exposure planning region of the buffer coat film from being exposed to light. Thus, the opening can be made with a high precision.

It is preferred that in the step of forming the sealed body, the pressurizing is performed at a pressure of 1.0 MPa or more. This case makes it possible to decrease the surface roughness of the film-formation planning surface of the cured body.

The semiconductor package producing method of the present invention further includes, for example, a step of yielding semiconductor packages by making the re-interconnection body into individual pieces.

The step of forming the re-interconnection body further includes, for example, a step of making a through hole which penetrates the cured body in the thickness direction thereof by radiating a laser through the opening onto the cured resin.

### Effect of the Invention

According to the method of the present invention for producing a semiconductor package, a periphery of a light-exposure planning region of a buffer coat film can be prevented from being exposed to light.

### BRIEF DESCRIPTION OF THE DRAWINGS

FIG. 1 is a sectional process chart referred to for describing a summary of a method of Embodiment 1.

FIG. 2 is a sectional process chart referred to for describing the summary of the method of Embodiment 1.

FIG. 3 is a sectional process chart referred to for describing the summary of the method of Embodiment 1.

FIG. 4 is a sectional process chart referred to for describing the summary of the method of Embodiment 1.

FIG. 5 is a sectional process chart referred to for describing the summary of the method of Embodiment 1.

FIG. 6 is a sectional process chart referred to for describing the summary of the method of Embodiment 1.

FIG. 7 is a schematic sectional view of a state of a stacked body arranged between a lower heating plate and an upper heating plate.

FIG. 8 is a sectional view that schematically illustrates a situation that the stacked body is hot-pressed in a parallel-flat-plate manner.

FIG. 9 is a sectional view that schematically illustrates a situation that from a sealed body obtained by the hot pressing, its separator is peeled off.

FIG. 10 is a schematic sectional view of the cured body and others that are obtained by heating the sealed body.

FIG. 11 is a schematic sectional view of the cured body after its temporarily-fixing material has been peeled.

FIG. 12 is a sectional view that schematically illustrates a situation that the cured body is partially ground.

FIG. 13 is a sectional view that schematically illustrates a situation that a buffer coat film is formed on the cured body.

FIG. 14 is a sectional view that schematically illustrates a situation that light for exposure is radiated on the buffer coat film.

FIG. 15 is a sectional view that schematically illustrates a situation after the light-exposed body has been developed.

FIG. 16 is a sectional view that schematically illustrates a situation that through holes are made.

FIG. 17 is a sectional view that schematically illustrates a situation that through electrodes are formed.

FIG. 18 is a sectional view that schematically illustrates a situation that a resist is formed on a seed layer.

FIG. 19 is a sectional view that schematically illustrates a situation that a plating pattern is formed on the seed layer.

FIG. 20 is a sectional view that schematically illustrates a situation that re-interconnections are completed.

FIG. 21 is a sectional view that schematically illustrates a situation that a protective film is formed on the re-interconnections.

FIG. 22 is a sectional view that schematically illustrates a situation that openings are made in the protective film.

FIG. 23 is a sectional view that schematically illustrates a situation that electrodes are formed on the re-interconnections.

FIG. 24 is a sectional view that schematically illustrates a situation that bumps are formed on the electrodes.

FIG. 25 is a schematic sectional view of semiconductor packages yielded by making the re-interconnection body into individual pieces.

### MODE FOR CARRYING OUT THE INVENTION

Hereinafter, the present invention will be described in detail by way of embodiments thereof. However, the invention is not limited only to these embodiments.

### Embodiment 1

A method of Embodiment 1 makes it possible to produce a fan-out type wafer level package (WLP).

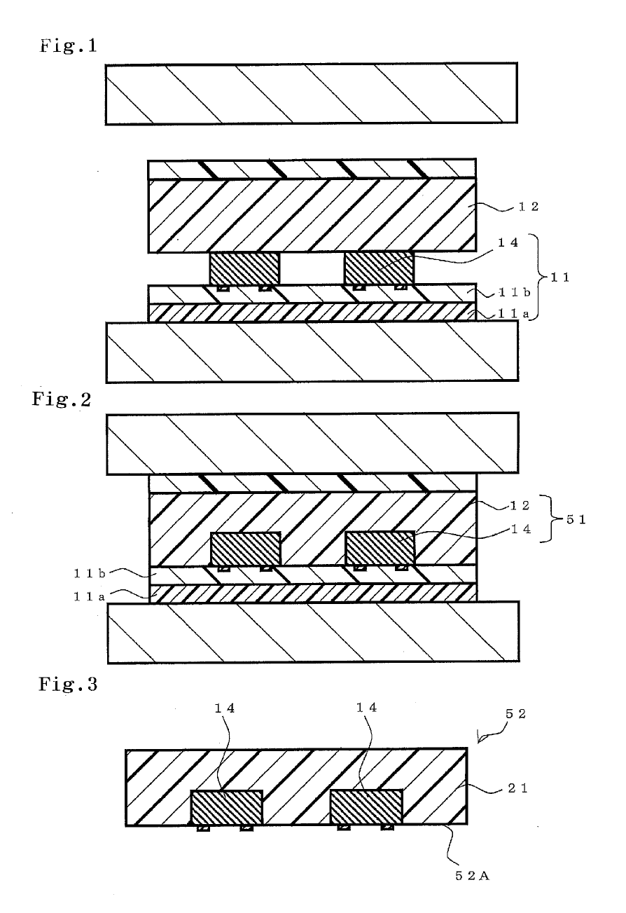

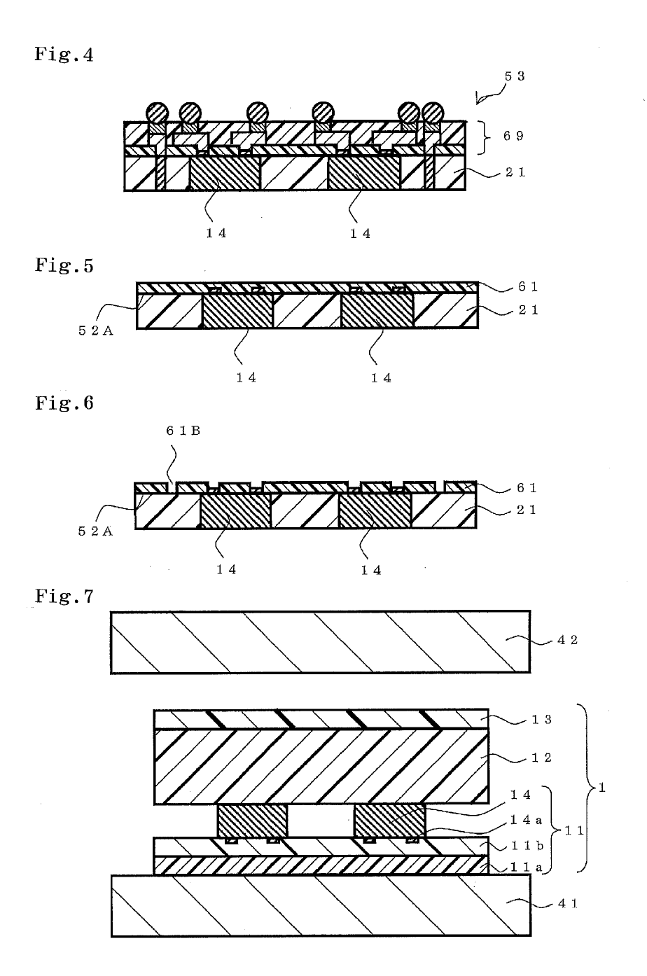

With reference to FIGS. 1 to 6, a description will be initially described in a summary of the semiconductor package producing method of Embodiment 1.

As illustrated in FIGS. 1 to 4, the semiconductor package producing method of Embodiment 1 includes: a step of forming a sealed body 51 by pressurizing a chip-temporarily-fixed body 11 including a supporting plate 11a, a temporarily-fixing material 11b stacked on the supporting plate 11a and semiconductor chips 14 fixed temporarily on the temporarily-fixing material 11b, and a thermosetting resin sheet 12 arranged on the chip temporarily-fixed body 11, the sealed body 51 including the semiconductor chips 14 and the thermosetting resin sheet 12 covering the semiconductor chips 14; a step of forming a cured body 52 by heating the sealed body 51 to cure the thermosetting resin sheet 12, the cured body 52 including the semiconductor chips 14 and a resultant cured resin 21 covering the semiconductor chips 14; a step of peeling off the temporarily-fixing material 11b from the cured body 52; and a step of forming a re-interconnection body 53 by forming a re-interconnection layer 69 onto a surface of the cured body 52 that had contacted the temporarily-fixing material 11b.

As illustrated in FIGS. 5 to 6, the step of forming the re-interconnection body 53 includes a step of forming a photosensitive buffer coat film 61 on the surface of the cured body 52 that had contacted the temporarily-fixing material 11b, and a step of making openings 61B in the buffer coat film 61 by subjecting the workpiece to exposure to light and development.

In a surface 52A of the cured body 52 that contacts the temporarily-fixing material 11b (this surface may be referred to as the film-formation planning surface hereinafter), the cured resin 21 has a surface roughness of 3000 nm or less, preferably 2500 nm or less, more preferably 2000 nm or less. The lower limit of the surface roughness is not particularly limited, and is, for example, 1 nm.

The surface roughness of the cured resin 21 is measurable by a method described in the item “EXAMPLES”.

In the method of Embodiment 1, the film-formation planning surface 52A of the cured body 52 is small in surface roughness. Accordingly, when the exposure light is radiated onto the buffer coat film 61, the exposure light is restrained from being irregularly reflected on the film-formation planning surface 52A. Thus, peripheries of light-exposure planning regions of the buffer coat film 61 can be prevented from being exposed to light so that the openings 61B can be made with a high precision.

The surface roughness of the cured resin 21 is controllable by the pressure when the chip temporarily-fixed body 11 and the thermosetting resin sheet 12 are pressurized, the heating temperature when the thermosetting resin sheet 12 is cured, the shape of an inorganic filler in the thermosetting resin sheet 12, the amount of the inorganic filler in the thermosetting resin sheet 12, and others. Out of these factors, important are the pressure when the chip temporarily-fixed body 11 and the thermosetting resin sheet 12 are pressurized, and the heating temperature when the thermosetting resin sheet 12 is cured. The surface roughness of the cured resin 21 can be made small, for example, by pressurizing the chip temporarily-fixed body 11 and the thermosetting resin sheet 12 at 1.0 MPa or more, lowering the heating temperature when the thermosetting resin sheet 12 is cured, making the average particle diameter of the inorganic filler small, or using, as the filler, a spherical inorganic filler.

Referring to FIGS. 7 to 25, the following will describe the semiconductor package producing method of Embodiment 1 in detail.

As illustrated in FIG. 7, a stacked body 1 has a chip temporarily-fixed body 11, a thermosetting resin sheet arranged on the chip temporarily-fixed body 11, and a separator 13 arranged on the thermosetting resin sheet 12. The stacked body 1 is arranged between a lower heating plate 41 and an upper heating plate 42.

The chip temporarily-fixed body 11 has a supporting plate 11a, a temporarily-fixing material 11b stacked on the supporting plate 11a, and semiconductor chips 14 temporarily fixed on the temporarily-fixing material 11b.

The material of the supporting plate 11a is not particularly limited, and examples thereof include metal materials such as SUS, and plastic materials such as polyimide, polyamideimide, polyetheretherketone, and polyethersulfone.

The temporarily-fixing material 11b is not particularly limited. This material may be a thermally foaming adhesive since the adhesive can easily be peeled off. The thermally foaming adhesive may be a thermally foaming adhesive known in the prior art.

The semiconductor chips 14 each have a circuit-forming surface on which electrode pads 14 a are formed. The chip temporarily-fixed body 11 is in a state that the circuit-forming surfaces of the semiconductor chips 14 contact the temporarily-fixing material 11b.

The thermosetting resin sheet 12 will be later described in detail.

As the separator 13, for example, a polyethylene terephthalate (PET) film is preferably usable. In order to peel off the thermosetting resin sheet 12 easily, the separator 13 is preferably subjected to release treatment.

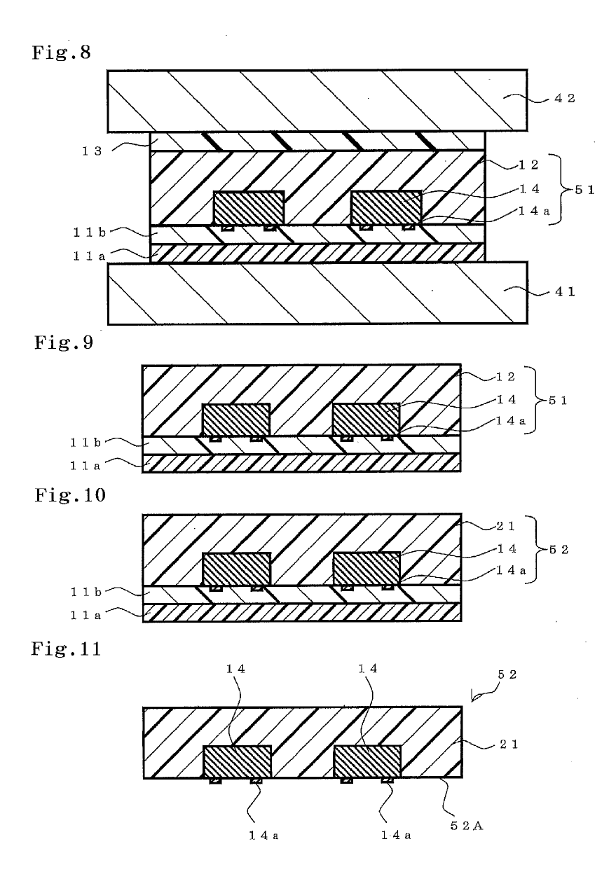

As illustrated in FIG. 8, the lower heating plate 41 and the upper heating plate 42 are used to hot-press the stacked body 1 in a parallel-flat-plate manner to form a sealed body 51.

The temperature for the hot pressing is preferably 70° C. or higher, more preferably 80° C. or higher. This case makes it possible to form the sealed body 51 easily. The temperature for the hot pressing is preferably 170° C. or lower, more preferably 150° C. or lower, even more preferably 110° C. or lower, even more preferably 100° C. or lower, in particular preferably 95° C. or lower. When the temperature is 170° C. or lower, the shaped body can be restrained from being warped.

The pressure for hot-pressing the stacked body 1 is preferably 1.0 MPa or more, more preferably 1.5 MPa or more. When the pressure is 1.0 MPa or more, a surface of the sealed body 51 that contacts the temporarily-fixing material 11b can be made small in surface roughness. As a result, a film-formation planning surface 52A of a cured body 52 to be obtained can be made small in surface roughness.

The pressure for hot-pressing the stacked body 1 is preferably 10 MPa or less, more preferably 8 MPa or less.

The period for the hot pressing is preferably 0.3 minutes or longer, more preferably 0.5 minutes or longer, even more preferably 2 minutes or longer. Moreover, the period for the hot pressing is preferably 60 minutes or shorter, more preferably 40 minutes or shorter, even more preferably 10 minutes or shorter, in particular preferably 5 minutes or shorter.

The hot pressing is conducted preferably in a reduced-pressure atmosphere. The hot pressing in the reduced-pressure atmosphere makes it possible to decrease the voids so that the thermosetting resin sheet can be satisfactorily embedded in the irregularities. About conditions for the reduced pressure, the pressure ranges, for example, from 0.1 to 5 kPa, preferably from 0.1 to 100 Pa.

The sealed body 51 yielded by hot-pressing the stacked body 1 has the semiconductor chips 14 and the thermosetting resin sheet 12 covering the semiconductor chips 14. The sealed body 51 contacts the temporarily-fixing material 11b and the separator 13.

As illustrated in FIG. 9, the separator 13 is peeled off from the sealed body 51.

Next, the sealed body 51 is heated at a temperature lower than the foaming starting temperature of the temporarily-fixing material 11b to cure the thermosetting resin sheet 12 to form the cured body 52 referred to above. The sealed body 51 is heated at, for example, a temperature at least 20° C. lower than the foaming starting temperature of the temporarily-fixing material 11b to cure the thermosetting resin sheet 12. This manner makes it possible to prevent the temporarily-fixing material 11b from being foamed before the thermosetting resin sheet 12 is cured. Thus, the film-formation planning surface 52A can be made small in surface roughness.

The heating temperature is preferably 100° C. or higher, more preferably 120° C. or higher, even more preferably 130° C. or higher, in particular preferably 140° C. or higher. In the meantime, the heating temperature is preferably 200° C. or lower, more preferably 180° C. or lower, even more preferably 170° C. or lower.

The heating period is preferably 10 minutes or longer, more preferably 30 minutes or longer. In the meantime, the upper limit of the heating period is preferably 180 minutes or shorter, more preferably 120 minutes or shorter, even more preferably 90 minutes or shorter.

When heated, the sealed body 51 may be pressurized. The pressure is preferably 0.1 MPa or more, more preferably 0.5 MPa or more. In the meantime, the upper limit thereof is preferably 10 MPa or less, more preferably 5 MPa or less.

As illustrated in FIG. 10, the cured body 52 has the semiconductor chips 14 and the resultant cured resin, which is represented by 21, this resin covering the semiconductor chips 14.

As illustrated in FIG. 11, the temporarily-fixing material 11b is heated to foam the temporarily-fixing material 11b, and subsequently the temporarily-fixing material 11b is peeled from the cured body 52. In this way, the film-formation planning surface 52A of the cured body 52 is made naked. The temperature at which the temporarily-fixing material 11b is heated is preferably 175° C. or higher, more preferably 180° C. or higher. When the temperature is 175° C. or higher, the temporarily-fixing material 11b can be satisfactorily foamed to be lowered in adhesive strength. The upper limit of the temperature at which the temporarily-fixing material 11b is heated is, for example, 200° C.

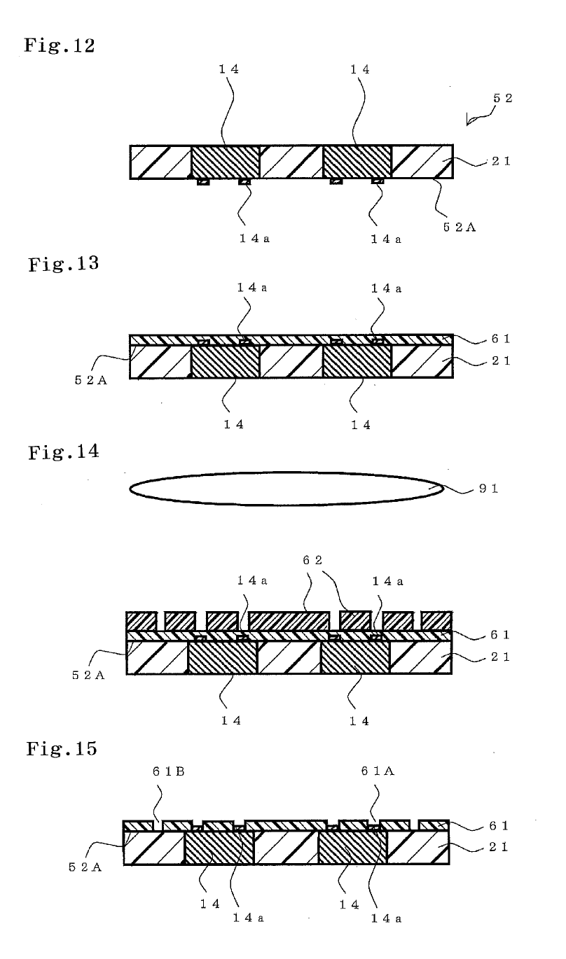

As illustrated in FIG. 12, a surface of the cured body 52 that is opposite to the film-formation planning surface 52A thereof may be ground. The grinding makes it possible to decrease a warp of the cured body 52 and further improve the thickness precision of the cured body 52. The ground thickness is arbitrary. For example, when the cured body 52 is ground to make the back surface of the semiconductor chips 14 naked, the warp of the cured body 52 can be remarkably decreased. The method for the grinding is, for example, a grinding method using a grindstone rotatable at a high speed.

As illustrated in FIG. 13, a buffer coat film 61 is formed on the film-formation planning surface 52A of the cured body 52. For the buffer coat film 61, for example, a photosensitive polyimide or a photosensitive polybenzoxazol (PBO) is usable. The method for forming the buffer coat film 61 is, for example, a spin coating method, a die coating method, or a method of laminating a dry film.

As illustrated in FIG. 14, a mask 62 is located onto the buffer coat film 61. Next, light for exposure is radiated from a light source 91 arranged above the buffer coat film 61, and the buffer coat film 61 is exposed to light.

Next, as illustrated in FIG. 15, the workpiece is developed to make openings 61A and openings 61B into the buffer coat film 61 to make predetermined portions of the cured resin 21 and electrode pads 14a naked.

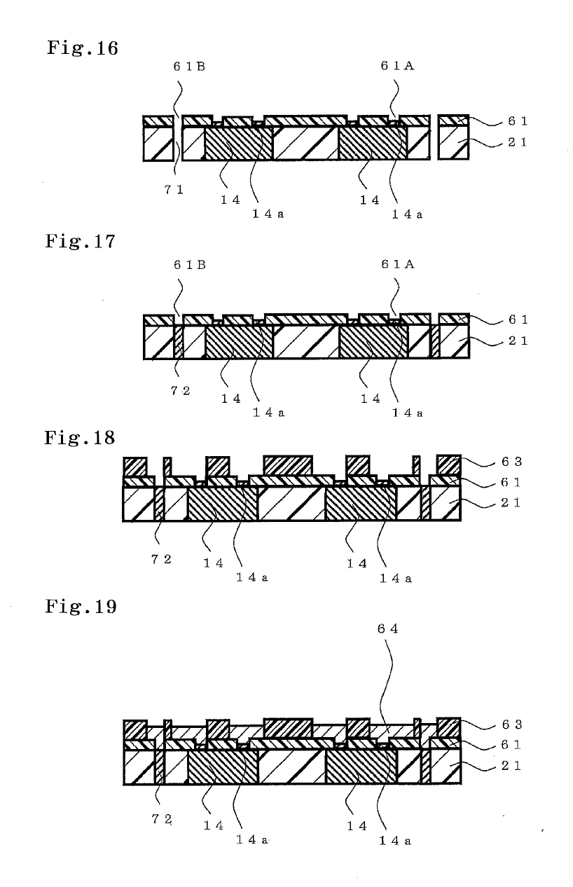

As illustrated in FIG. 16, a laser is radiated from above the cured body 52 through the openings 61B to the cured resin 21 to make through holes 71. The through holes 71 penetrate the cured body 52 into the thickness direction thereof.

As illustrated in FIG. 17, a metal is filled into the through holes 71 to form through electrodes 72. The through electrodes 72 penetrate the cured body 52 into the thickness direction thereof. Examples of the filled metal include Cu, Ag, Au, Sn, and any eutectic solder. The eutectic solder may be, for example, Sn—Ag eutectic solder, or Sn—Ag—Cu eutectic solder.

Next, a seed layer is formed on the buffer coat film 61, the electrode pads 14 a and the through electrodes 72.

As illustrated in FIG. 18, a resist 63 is formed onto the seed layer.

As illustrated in FIG. 19, a plating pattern 64 is formed onto the seed layer by a plating method such as electroplating.

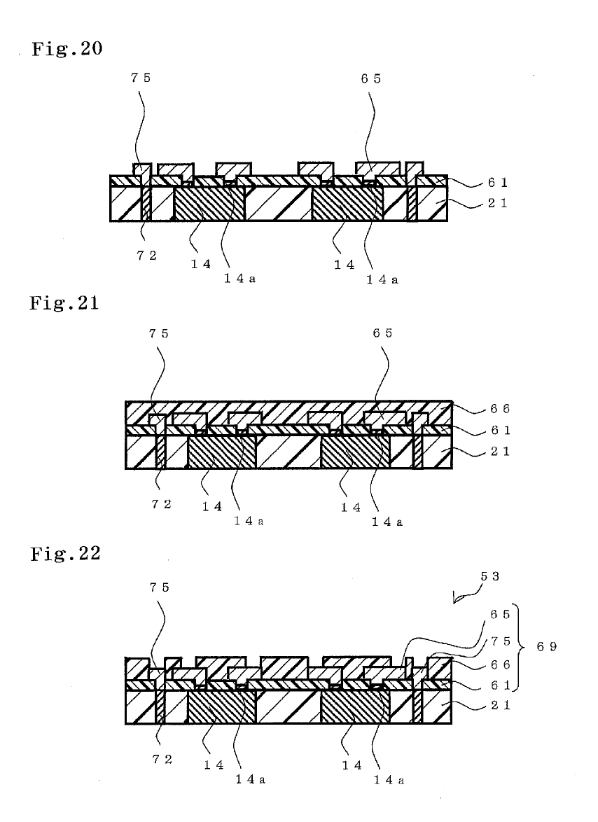

As illustrated in FIG. 20, the resist 63 is removed, and then the seed layer is etched to complete a re-interconnection 65 and a re-interconnection 75.

As illustrated in FIG. 21, a protective film 66 is formed onto the re-interconnection 65 and the re-interconnection 75.

For the protective film 66, for example, a photosensitive polyimide or a photosensitive polybenzoxazole (PBO) is usable.

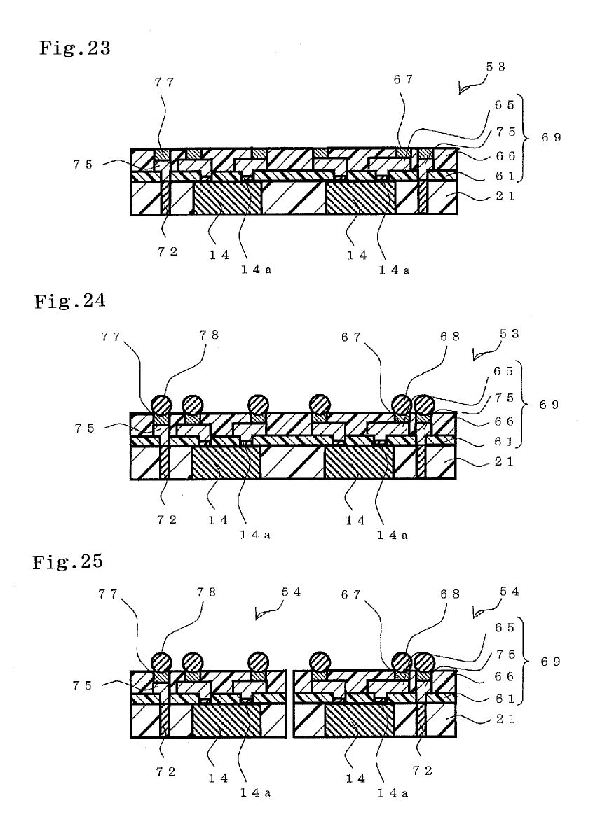

As illustrated in FIG. 22, openings are made in the protective film 66 to make portions of the re-interconnection 65 and the re-interconnection 75 that are positioned under the protective film 66 naked. In this way, a re-interconnection layer 69 including the re-interconnection 65 and the re-interconnection 75 is finished on the cured body 52 to yield a re-interconnection body 53 having the cured body 52 and the re-interconnection layer 69 formed on the cured body 52.

As illustrated in FIG. 23, electrodes (UBM: under bump metal) 67 are formed on the naked re-interconnection 65. Moreover, electrodes 77 are formed on the re-interconnection 75.

As illustrated in FIG. 24, bumps 68 are formed on the electrodes 67, respectively. The bumps 68 are electrically connected through the electrodes 67 and the re-interconnection 65 to the electrode pads 14 a. Moreover, bumps 78 are formed on the electrodes 77, respectively. The bumps 78 are electrically connected through the electrodes 77 and the re-interconnection 75 to the respective through electrodes 72.

As illustrated in FIG. 25, the re-interconnection body 53 is divided (or diced) into individual pieces to yield semiconductor packages 54.

The above-mentioned process makes it possible to yield the semiconductor packages 54, in each of which the interconnections are led to the outside of a chip region of the package.

### Thermosetting Resin Sheet 12:

About the thermosetting resin sheet 12, a description will be made.

The thermosetting resin sheet 12 may be a thermosetting resin sheet curable at a temperature lower than the foaming starting temperature of the temporarily-fixing material 11b.

The thermosetting resin sheet 12 preferably contains a thermosetting resin such as an epoxy resin or a phenolic resin.

The epoxy resin is not particularly limited, and examples thereof include triphenyl methane type epoxy resin, cresol novolak type epoxy resin, biphenyl type epoxy resin, modified bisphenol A type epoxy resin, bisphenol A type epoxy resin, bisphenol F type epoxy resin, modified bisphenol F type epoxy resin, dicyclopentadiene type epoxy resin, phenol novolak type epoxy resin, phenoxy resin, and other various epoxy resins. These epoxy resins may be used alone or in combination of two or more thereof.

In order to secure reactivity, the epoxy resin is preferably a resin which has an epoxy equivalent of 150 to 250, and has a softening point or melting point of 50 to 130° C. to be solid at room temperature. Out of species of the epoxy resin, more preferred are triphenylmethane type epoxy resin, cresol novolak type epoxy resin, and biphenyl type epoxy resin from the viewpoint of the reliability of the resin sheet. Preferred is bisphenol F type epoxy resin.

The phenolic resin is not particularly limited as long as it initiates a curing reaction with an epoxy resin. Examples thereof include a phenol novolak resin, a phenolaralkyl resin, a biphenylaralkyl resin, a dicyclopentadiene-type phenolic resin, a cresol novolak resin, and a resol resin. These phenolic resins may be used either alone or in combination of two or more thereof.

A phenolic resin having a hydroxyl equivalent of 70 to 250 and a softening point of 50° C. to 110° C. is preferably used from the viewpoint of reactivity with the epoxy resin. Among these phenolic resins, a phenol novolak resin can be preferably used from the viewpoint of its high curing reactivity. Further, a phenolic resin having low moisture absorption such as a phenolaralkyl resin and a biphenylaralkyl resin can also be suitably used from the viewpoint of its reliability.

The total content of the epoxy resin and the phenolic resin in the thermosetting resin sheet 12 is preferably 5% or more by weight. When the total content is 5% or more by weight, the sheet can satisfactorily gain an adhesive strength onto the semiconductor chips 14 and others. The total content of the epoxy resin and the phenolic resin in the thermosetting resin sheet 12 is preferably 40% or less by weight, more preferably 20% or less by weight. When the total content is 40% or less by weight, the sheet 12 can be controlled to be low in hygroscopicity.

From the viewpoint of curing reactivity, the compounding ratio of the epoxy resin to the phenolic resin is preferably set so that the total amount of the hydroxy groups in the phenolic resin is 0.7 equivalent to 1.5 equivalents, and more preferably 0.9 equivalent to 1.2 equivalents per one equivalent of the epoxy groups in the epoxy resin.

The thermosetting resin sheet 12 preferably contains a curing promoter.

The curing promoter is not particularly limited as long as it promotes curing of the epoxy resin and the phenolic resin. Examples thereof include imidazole-based curing promoters such as 2-methylimidazole (trade name; 2MZ), 2-undecylimidazole (trade name; C11-Z), 2-heptadecylimidazole (trade name; C17Z), 1,2-dimethylimidazole (trade name; 1.2DMZ), 2-ethyl-4-methylimidazole (trade name; 2E4MZ), 2-phenylimidazole (trade name; 2PZ), 2-phenyl-4-methylimidazole (trade name; 2P4MZ), 1-benzyl-2-methylimidazole (trade name; 1B2MZ), 1-benzyl-2-phenylimidazole (trade name; 1B2PZ), 1-cyanoethyl-2-methylimidazole (trade name; 2MZ-CN), 1-cyanoethyl-2-undecylimidazole (trade name; C11Z-CN), 1-cyanoethyl-2-phenylimidazolium trimellitate (trade name; 2PZCNS-PW), 2,4-diamino-6-[2′-methylimidazolyl-(1′)]-ethyl-s-triazine (trade name; 2MZ-A), 2,4-diamino-6-[2′-undecylimidazolyl-(1′)]-ethyl-s-triazine (trade name; C11Z-A), 2,4-diamino-6-[2′-ethyl-4′-methylimidazolyl-(1′)]-ethyl-s-triazine (trade name; 2E4MZ-A), 2,4-diamino-6-[2′-metthylimidazolyl-(1′)]-ethyl-s-triazine isocyanuric acid adduct (trade name; 2MA-OK), 2-phenyl-4,5-dihydroxymethylimidazole (trade name; 2PHZ-PW), and 2-phenyl-4-methyl-5-hydroxymethylimidazole (trade name; 2P4MZ-PW) (all of these compounds are manufactured by Shikoku Chemicals Corporation).

Particularly preferred are imidazole curing promoters since the promoters restrain curing reaction at the kneading temperature. More preferred are 2-phenyl-4,5-dihydroxymethylimodazole, and 2,4-diamino-6-[2′-ethyl-4′-methylimidazolyl-(1′)]ethyl-s-triazine; and even more preferred is 2-phenyl-4,5-dihydroxymethylimodazole.

The content of the curing promoter is preferably 0.2 parts or more, more preferably 0.5 parts or more, even more preferably 0.8 parts or more by weight for 100 parts by weight of the total of the epoxy resin and the phenolic resin. The content of the curing promoter is preferably 5 parts or less, more preferably 2 parts or less by weight for 100 parts by weight of the total of the epoxy resin and the phenolic resin.

The thermosetting resin sheet 12 may contain a thermoplastic resin (elastomer).

Examples of the thermoplastic resin include natural rubber, butyl rubber, isoprene rubber, chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, a fluoro resin, a styrene-isobutylene-styrene triblock copolymer, and a methylmethacrylate-butadiene-styrene copolymer (MBS resin). These thermoplastic resins may be used alone or in combination of two or more thereof.

The content of the thermoplastic resin(s) in the thermosetting resin sheet 12 is preferably 1% or more by weight. When the content is 1% or more by weight, softness and flexibility can be given to the sheet 12. The content of the thermoplastic resin(s) in the thermosetting resin sheet 12 is preferably 30% or less, more preferably 10% or less, even more preferably 5% or less by weight. When the content is 30% or less by weight, the sheet 12 can satisfactorily gain adhering strength to the semiconductor chips 14 and others.

The thermosetting resin sheet 12 preferably contains an inorganic filler. By incorporating the inorganic filler thereinto, the sheet 12 can be decreased in thermal expansion coefficient α.

Examples of the inorganic filler include quartz glass, talc, silica (fused silica, crystalline silica, etc.), alumina, aluminum nitride, silicon nitride, and boron nitride. Among these inorganic fillers, silica and alumina are preferable, and silica is more preferable because the thermal expansion coefficient can be reduced well. Silica is preferably fused silica and more preferably spherical fused silica because of its excellent fluidity.

The average particle diameter of the inorganic filler is preferably 1 μm or more, more preferably 5 μm or more. When the average particle diameter is 1 μm or more, the thermosetting resin sheet 12 easily gains flexibility and softness. The average particle diameter of the inorganic filler is preferably 50 μm or less, more preferably 30 μm or less. When the average particle diameter is 50 μm or less, the inorganic filler is easily filled into the sheet to a high degree.

The average particle diameter can be derived, for example, by using a sample extracted at will from a population thereof, and measuring the sample by use of a laser diffraction scattering type particle size distribution measuring instrument.

The inorganic filler is preferably treated (pretreated) with a silane coupling agent. By this treatment, wettability of the inorganic filler to the resin can be improved, and dispersibility of the inorganic filler can be enhanced.

The silane coupling agent is a compound having a hydrolyzable group and an organic functional group in a molecule.

Examples of the hydrolyzable group include alkoxy groups having 1 to 6 carbon atoms such as a methoxy group and an ethoxy group, an acetoxy group, and a 2-mthoxyrthoxy group. Among these, a methoxy group is preferable because it is easy to remove a volatile component such as an alcohol generated by hydrolysis.

Examples of the organic functional group include a vinyl group, an epoxy group, a styryl group, a methacrylic group, an acrylic group, an amino group, a ureido group, a mercapto group, a sulfide group, an isocyanate group. Among these, an epoxy group is preferable because the epoxy group can easily react with an epoxy resin and a phenolic resin.

Examples of the silane coupling agent include vinyl group-containing silane coupling agents such as vinyltrimethoxysilane and vinyltriethoxysilane; epoxy group-containing silane coupling agents such as 2-(3,4-epoxycyclohexyl)ethyltrimethoxysilane and 3-glycidoxypropyl methyldimethoxysilane, 3-glycidoxypropyl trimethoxysilane, 3-glycidoxypropyl methyldiethoxysilane, and 3-glycidoxypropyl triethoxysilane; styryl group-containing silane coupling agents such as p-styryltrimethoxysilane; methacrylic group-containing silane coupling agents such as 3-methacryloxypropylmethyldimethoxysilane, 3-methacryloxypropyltrimethoxysilane, 3-methacryloxypropylmethyldiethoxysilane, and 3-methacryloxypropyltriethoxysilane; acrylic group-containing silane coupling agents such as 3-acryloxypropyltrimethoxysilane; amino group-containing silane coupling agents such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysialne, 3-triethoxysilyl-N-(1,3-dimethyl-butylidene)propylamine, N-phenyl-3-aminopropyltrimethoxysialne, and N-(vinylbenzyl)-2-aminoethyl-3-aminopropyltrimethoxysilane; ureido group-containing silane coupling agents such as 3-ureidopropyltriethoxysilane; mercapto group-containing silane coupling agents such as 3-mercaptopropylmethyldimethoxysilane and 3-mercaptopropyltrimethoxysilane; sulfide group-containing silane coupling agents such as bis(triethoxysilylpropyl)tetrasulfide; and isocyanate group-containing silane coupling agents such as 3-isocyanatepropyltriethoxysilane.

A method of treating the inorganic filler with the silane coupling agent is not especially limited, and examples thereof include a wet method of mixing the inorganic filler and the silane coupling agent in a solvent and a dry method of treating the inorganic filler with the silane coupling agent in a gas phase.

The amount of the silane coupling agent to be used for the treatment is not especially limited; however, 0.1 to 1 part by weight of the silane coupling agent is preferably used for the treatment to 100 parts by weight of the non-treated inorganic filler.

The content of the inorganic filler in the thermosetting resin sheet 12 is preferably 20% or more, more preferably 70% or more, even more preferably 74% or more by volume. In the meantime, the content of the inorganic filler is preferably 90% or less, more preferably 85% or less by volume. When the content is 90% or less by volume, the sheet 12 can gain a good irregularity-following performance.

The content of the inorganic filler can be described by using “% by weight” as a unit. As a typical example, the content of silica is described by using “% by weight” as a unit.

The specific gravity of silica is normally 2.2 g/cm³. Therefore, a preferred range of the content (% by weight) of silica is as follows.

The content of silica in the thermosetting resin sheet 12 is preferably 81% by weight or more, and more preferably 84% by weight or more. The content of silica in the thermosetting resin sheet 12 is preferably 94% by weight or less, and more preferably 91% by weight or less.

The specific gravity of alumina is normally 3.9 g/cm³. Therefore, a preferred range of the content (% by weight) of alumina is as follows.

The content of alumina in the thermosetting resin sheet 12 is preferably 88% by weight or more, and more preferably 90% by weight or more. The content of alumina in the thermosetting resin sheet 12 is preferably 97% by weight or less, and more preferably 95% by weight or less.

Besides the components described above, the thermosetting resin sheet 12 may contain, as needed, other compounding agents generally used in manufacture of a sealing resin, such as a flame retardant component, a pigment, and a silane coupling agent.

Examples of the flame retardant component include various types of metal hydroxides such as aluminum hydroxide, magnesium hydroxide, iron hydroxide, calcium hydroxide, tin hydroxide, and complex metal hydroxides; and a phosphazene compound. Among these flame retardant components, a phosphazene compound is preferable because of its excellent flame retardancy and strength after curing.

The pigment is not particularly limited, and an example thereof is carbon black.

The method for producing the thermosetting resin sheet 12 is not particularly limited, and is preferably a method of kneading the above-mentioned individual components (for example, the epoxy resin, phenolic resin, inorganic filler and curing promoter) to yield a kneaded product, and working the product plastically into a sheet form. This method makes it possible to fill the inorganic filler highly and design the thermal expansion coefficient of the sheet 12 to a low value.

Specifically, the epoxy resin, the phenolic resin, the inorganic filler, the curing promoter, etc. are melted and kneaded using a known kneader such as a mixing roll, a pressurizing kneader, and an extruder to prepare a kneaded product, and the obtained kneaded product is subjected to plastic working to form a sheet. As kneading conditions, the upper limit of the temperature is preferably 140° C. or lower, and more preferably 130° C. or lower. The lower limit of the temperature is preferably higher than or equal to the softening point of components described above, and is 30° C. or higher, and preferably 50° C. or higher, for example. The kneading time is preferably 1 to 30 minutes. The kneading is preferably performed under a reduced pressure condition (under a reduced pressure atmosphere), and the pressure under the reduced pressure condition is 1×10⁻⁴ to 0.1 kg/cm², for example.

It is preferred to apply the plastic working to the kneaded product after the melt kneading in the state that the kneaded product keeps a high temperature without being cooled. The method for the plastic working is not particularly limited, and examples thereof include flat plate pressing, T-die extrusion, screw die extrusion, rolling, roll kneading, inflation extrusion, co-extrusion, and calendering methods. The plastic working temperature is preferably not lower than the respective softening points of the above-mentioned individual components, and is, for example, from 40 to 150° C., preferably from 50 to 140° C., more preferably from 70 to 120° C., considering the thermosetting property and the moldability of the epoxy resin.

It is also preferred to produce the thermosetting resin sheet 12 in an applying or coating manner. The thermosetting resin sheet 12 can be produced, for example, by producing an adhesive composition solution containing the above-mentioned individual components, applying the adhesive composition solution into a predetermined thickness onto a substrate separator to form a coating film, and then drying the coating film.

A solvent used for the adhesive composition solution is not particularly limited, and is preferably an organic solvent in which the individual components can be evenly dispersed, kneaded or dispersed. Examples thereof include dimethylformamide, dimethylacetoamide, N-methylpyrrolidone, ketone solvents such as acetone, methyl ethyl ketone and cyclohexanone, toluene, and xylene.

The substrate separator may be polyethylene terephthalate (PET), polyethylene or polypropylene, or a film or paper piece having a surface coated with a peeling agent such as a fluorine-containing peeling agent or a long-chain alkyl acrylate peeling agent. The method for applying the adhesive composition solution is, for example, roll coating, screen coating or gravure coating. Conditions for drying the coating film are not particularly limited, and are, for example, as follows: a drying temperature of 70 to 160° C. and a drying period of 1 to 5 minutes.

The thickness of the thermosetting resin sheet 12 is not particularly limited; however, it is preferably 100 μm or more, and more preferably 150 μm or more. The thickness of the thermosetting resin sheet 12 is preferably 2,000 μm or less, and more preferably 1,000 μm or less. If the thickness is within the above-described range, the semiconductor chip 14 can be sealed well.

### Embodiment 2

In Embodiment 1, the stacked body 1 is hot-pressed in a parallel-flat-plate manner to form the sealed body 51, and the sealed body 51 is next heated to form the cured body 52. In Embodiment 2, the cured body 52 is formed by press forming (compressive forming) using a mold.

Specifically, a molding apparatus is used to pressurize the stacked body 1 while this body is heated. In this way, the cured body 52 is formed. Of course, before the cured body 52 is formed, the sealed body 51 is formed.

When the stacked body 1 is pressurized by the compressive forming, a preferred range of the pressure, that is, the pressure for fastening parts of the mold to each other is the same range as preferred for the hot pressing pressure in Embodiment 1.

The temperature when the stacked body 1 is pressurized is not particularly limited as far as the temperature is a temperature permitting the thermosetting resin sheet 12 to be cured. The temperature when the stacked body 1 is pressurized is preferably 100° C. or higher, more preferably 130° C. or higher, even more preferably 140° C. or higher. By heightening the temperature when the stacked body 1 is pressurized, the cured body 52 can be formed. The temperature when the stacked body 1 is pressurized is preferably 170° C. or lower, more preferably 160° C. or lower, even more preferably 150° C. or lower. When the temperature is 170° C. or lower, the shaped body can be restrained from being warped.

When the stacked body 1 is pressurized, a preferred range of the pressurizing period is the same range as preferred for the hot pressing period in Embodiment 1.

Next, in order to cure the cured resin 21 of the cured body 52 further, the cured body 52 may be further heated. In other words, a post mold cure step, which is generally called PMC, may be performed.

The temperature at which the cured body 52 is heated is preferably 100° C. or higher, more preferably 120° C. or higher, even more preferably 130° C. or higher, in particular preferably 140° C. or higher. In the meantime, the temperature at which the cured body 52 is heated is preferably 200° C. or lower, more preferably 180° C. or lower, even more preferably 170° C. or lower.

The heating period when the cured body 52 is heated is preferably 10 minutes or longer, more preferably 30 minutes or longer. In the meantime, the upper limit of the heating period is preferably 180 minutes or shorter, more preferably 120 minutes or shorter, even more preferably 90 minutes or shorter.

As illustrated in FIG. 11, after the temporarily-fixing material 11b is heated to be foamed, the temporarily-fixing material 11b is peeled off from the cured body 52. In this way, the film-formation planning surface 52A of the cured body 52 is made naked. The temperature at which the temporarily-fixing material 11b is heated is preferably 175° C. or higher, more preferably 180° C. or higher. When the temperature is 175° C. or higher, the temporarily-fixing material 11b can be satisfactorily foamed to be lowered in adhesive strength. The upper limit of the temperature at which the temporarily-fixing material 11b is heated is, for example, 200° C.

The step of peeling off the temporarily-fixing material 11b from the cured body 52 may be performed before the post-curing step.

Subsequent steps can be performed in the same way as in Embodiment 1.

### EXAMPLES

Hereinafter, preferred examples of this invention will be illustratively described in detail. However, about materials, blended amounts and others that are described in the examples, the scope of this invention is not limited only to these described matters unless the specification especially includes a restrictive description thereabout.

### [Resin Sheets]

Resin sheets A to C are as follows:

### Components Used to Produce Each Resin Sheet A:

Components used to produce a resin sheet A are as follows.

Epoxy resin: YSLV-80XY, manufactured by Nippon Steel Chemical Corp. (bisphenol F type epoxy resin; epoxy equivalent: 200 g/eq., and softening point: 80° C.)

Phenolic resin: MEH-7851-SS, manufactured by Meiwa Plastic Industries, Ltd. (phenol novolak resin having a biphenylaralkyl skeleton; hydroxyl equivalent: 203 g/eq., and softening point: 67° C.)

Curing promoter: 2PHZ-PW, manufactured by Shikoku Chemicals Corp. (2-phenyl-4,5-dihydroxymethylimidazole)

Elastomer: SIBSTAR 072T, manufactured by Kaneka Corp. (styrene-isobutylene-styrene triblock copolymer)

Inorganic filler: FB-9454, manufactured by Denka Co., Ltd. (spherical fused silica powder ; average particle diameter: 20 μm)

Silane coupling agent: KBM-403, manufactured by Shin-Etsu Chemical Co., Ltd. (3-glycidoxypropyltrimethoxysilane)

Carbon black: #20, manufactured by Mitsubishi Chemical Corp.

### Production of Resin Each Sheet A:

In accordance with blend proportions described in Table 1, individual components were blended with each other in a mixer, and then melt-kneaded at 120° C. for 2 minutes in a biaxial kneader. Subsequently, the kneaded product was extruded through a T die to produce a resin sheet A having a thickness of 500 μm.

### Components Used to Produce Each Resin Sheet B:

Components used to produce each resin sheet B are as follows:

Epoxy resin: YSLV-80XY (bisphenol F type epoxy resin; epoxy equivalent: 200 g/eq., and softening point: 80° C.) manufactured by Nippon Steel Chemical Co., Ltd.

Phenolic resin: MEH-7851-SS (phenolic novolak resin having a biphenylaralkyl skeleton; hydroxyl equivalent: 203 g/eq., and softening point: 67° C.) manufactured by Meiwa Plastic Industries, Ltd.

Curing promoter: 2PHZ-PW (2-phenyl-4,5-dihydroxymethylimidazole) manufactured by Shikoku Chemicals Corp.

Elastomer: SIBSTAR 072T (styrene-isobutylene-styrene triblock copolymer) manufactured by Kaneka Corp.

Inorganic filler: CRYSTALITE 3K-S (crushed silica powder; average particle diameter: 35 μm), manufactured by Denka Co., Ltd.

Silane coupling agent: KBM-403 (3-glycidoxypropyltrimethoxysilane), manufactured by Shin-Etsu Chemical Co., Ltd.

Carbon black: #20 manufactured by Mitsubishi Chemical Corp.

### Production of Each Resin Sheet B:

In accordance with blend proportions described in Table 1, individual components were blended with each other in a mixer, and the resultant blend was melted and kneaded at 120° C. in a biaxial kneader for 2 minutes. Subsequently, the blend was extruded through a T die to produce each resin sheet B having a thickness of 500 μm.

### Components Used to Produce Each Resin Sheet C:

Components used to produce each resin sheet C are as follows:

Epoxy resin: KI-3000 (o-cresol novolak resin type epoxy resin; epoxy equivalent: 200 g/eq.), manufactured by Tohto Kasei Co., Ltd.

Epoxy resin: EPIKOTE 828 (bisphenol A type epoxy resin; epoxy equivalent: 200 g/eq.), manufactured by Mitsubishi Chemical Corp.

Phenolic resin: MEH-7851-SS (phenolic novolak resin having a biphenylaralkyl skeleton; hydroxyl equivalent: 203 g/eq., and softening point: 67° C.) manufactured by Meiwa Plastic Industries, Ltd.

Curing promoter: 2PHZ-PW (2-phenyl-4,5-dihydroxymethylimidazole) manufactured by Shikoku Chemicals Corp.

Inorganic filler: MUF-3V (spherical fused silica powder; average particle diameter: 3.5 μm), manufactured by Tatsumori Ltd.

Carbon black: #20 manufactured by Mitsubishi Chemical Corp.

### Production of Each Resin Sheet C:

In accordance with blend proportions described in Table 1, the epoxy resins, the phenolic resin, methyl ethyl ketone (MEK) and the inorganic filler were incorporated into a container to give a solid concentration of 95%. A planetary centrifugal mixer (manufactured by Thinky Corp.) was used to stir the blend at 800 rpm for 5 minutes. Thereafter, the curing promoter and the carbon black were added thereto. Next, MEK was added thereto to give a solid concentration of 90%, and the resultant was stirred at 800 rpm for 3 minutes to yield a coating liquid. The coating liquid was applied onto a polyethylene terephthalate film (thickness: 50 μm) subjected to silicone release treatment. The coating liquid was then dried at 120° C. for 3 minutes to produce a sheet having a thickness of 100 μm. A roll laminator was used to bond plural pieces from the sheet to each other to yield a resin sheet C having a thickness of 500 μm.

TABLE 1
Resin sheet A:

| | | Resin sheet A |
|---|---|---|
| Blend | YSLV-80XY (epoxy resin) | 453.3 |
| (parts by | MEH-7851-SS (phenolic resin) | 479.4 |
| weight) | 2PHZ-PW (curing promoter) | 9.3 |
| | SIBSTAR 072T (elastomer) | 228 |
| | FB-9454 (inorganic filler) | 8800 |
| | KBM-403 (silane coupling agent) | 4.4 |
| | #20 (carbon black) | 30 |

| | |
|---|---|
| Total (parts by weight) | 10004.4 |

Resin sheet B :

| | | Resin sheet B |
|---|---|---|
| Blend | YSLV-80XY (epoxy resin) | 453.3 |
| (parts by | MEH-7851-SS (phenolic resin) | 479.4 |
| weight) | 2PHZ-PW (curing promoter) | 9.3 |
| | SIBSTAR 072T (elastomer) | 228 |
| | CRYSTALITE 3K-S (inorganic filler) | 8800 |
| | KBM-403 (silane coupling agent) | 4.4 |
| | #20 (carbon black) | 30 |

| | |
|---|---|
| Total (parts by weight) | 10004.4 |

Resin sheet C:

| | | Resin sheet C |
|---|---|---|
| Blend | KI-3000 (epoxy resin) | 146.9 |
| (parts by | EPIKOTE 828 (epoxy resin) | 145.3 |
| weight) | MEH-7851-SS (phenolic resin) | 291 |
| | 2PHZ-PW (curing promoter) | 4.5 |
| | MUF-3V (inorganic filler) | 2706.2 |
| | #20 (carbon black) | 9.6 |

| | |
|---|---|
| Total (parts by weight) | 3303.5 |

### [Method for Producing Cured Bodies]

About a method for producing a cured body in each of working examples and comparative examples, a description will be made.

### Examples 1 to 3 and Comparative Examples 1 to 2

In each of these examples, a temporarily-fixing pressure-sensitive adhesive sheet (No. 3195V, manufactured by Nitto Denko Corp.) was laminated onto a glass plate (TEMPAX glass) having a size of 300 mm×400 mm×1.4 mm thickness. Next, semiconductor elements each having a size of 6 mm×6 mm×200 μm thickness were arranged at intervals of 9 mm onto the temporarily-fixing pressure-sensitive adhesive sheet. Next, in accordance with Table 2, any one of the resin sheet species was selected, and then arranged onto the semiconductor elements. Next, a separator was arranged onto the resin sheet to yield a stacked body. A high-precision vacuum pressurizing apparatus (manufactured by Mikado Technos Co., Ltd.) was used to press the stacked body in a parallel-flat-plate manner under conditions shown in Table 2, thereby yielding a sealed body to which the temporarily-fixing pressure-sensitive adhesive sheet and the separator were attached. Thereafter, the separator was peeled off from the sealed body.

The sealed body, to which the temporarily-fixing pressure-sensitive adhesive sheet was attached, was heated under conditions shown in Table 2 to cure the resin region of the sealed body, thereby yielding a cured body to which the temporarily-fixing pressure-sensitive adhesive sheet was attached. In order to foam the temporarily-fixing pressure-sensitive adhesive sheet, the cured body, to which the temporarily-fixing pressure-sensitive adhesive sheet was attached, was heated at 185° C. for 5 minutes, and then the temporarily-fixing pressure-sensitive adhesive sheet was peeled from the cured body.

### Examples 4 to 5

In each of these examples, a temporarily-fixing pressure-sensitive adhesive sheet (No. 3195V, manufactured by Nitto Denko Corp.) was laminated onto a glass plate (TEMPAX glass) having a size of 300 mm×300 mm×1.1 mm thickness. Next, semiconductor elements each having a size of 6 mm×6 mm×200 μm thickness were arranged at intervals of 9 mm onto the temporarily-fixing pressure-sensitive adhesive sheet. Next, in accordance with Table 2, any one of the resin sheet species was selected, and then arranged onto the semiconductor elements. Next, a separator was arranged onto the resin sheet to yield a stacked body. A molding apparatus (WCM-300, manufactured by Apic Yamada Corp.) was used to form the stacked body into a shape while the stacked body was pressurized and heated under conditions shown in Table 2, thereby forming a sealed body to which the temporarily-fixing pressure-sensitive adhesive sheet and the separator were attached. Thereafter, the separator was peeled off from the sealed body.

The sealed body, to which the temporarily-fixing pressure-sensitive adhesive sheet was attached, was heated under conditions shown in Table 2 to cure the resin region of the sealed body, thereby yielding a cured body to which the temporarily-fixing pressure-sensitive adhesive sheet was attached. In order to foam the temporarily-fixing pressure-sensitive adhesive sheet, the cured body, to which the temporarily-fixing pressure-sensitive adhesive sheet was attached, was heated at 185° C. for 5 minutes, and then the temporarily-fixing pressure-sensitive adhesive sheet was peeled from the cured body.

### [Evaluations]

About each of the cured bodies, evaluations described below were made. The results are shown in Table 2.

### Surface Roughness (Ra):

About the surface of the cured body that had contacted the temporarily-fixing pressure-sensitive adhesive sheet, the surface roughness of its cured resin region was measured.

On the basis of JIS B 0601, the surface roughness was measured, using a noncontact three-dimensional surface roughness tester (NT3300) manufactured by Veeco Instruments Inc. About a condition for the measurement, the magnifying power was set to 50. Measurement values were obtained by multiplying measured data by a median filter. The measurement was made 5 times while a site of the surface to be measured was changed. The average value thereof was defined as the surface roughness.

### Exposure to Light and Development:

The cured body was spin-coated with a positive type photosensitive polyimide solution (PIMEL I-700, manufactured by Asahi Kasei E-materials Corp.). Next, the workpiece was pre-baked at 100° C. for 3 minutes to form a polyimide film into a thickness of 10 μm on the cured body surface that had contacted the temporarily-fixing pressure-sensitive adhesive sheet. From a super high pressure mercury lamp, a light ray having a wavelength of 436 nm was radiated, through a glass mask to which a 50-μm-diameter-hole exposure-pattern was attached, onto the polyimide film at 350 mJ/cm². After the radiation, the resultant was developed with a 2.38%-by-weight solution of tetramethylammonium hydroxide in water that had a temperature of 25° C. for 5 minutes. The workpiece was cleaned with ion exchange water, and then dried at 80° C. for 1 hour. Subsequently, the diameter of each of ten out of the resultant openings was measured. When the measured sample was a sample in which the respective diameters of the entire openings were from 45 to 55 μm, the sample was determined to be ◯; or when the measured sample was a sample in which at least one of these diameters was outside the range of 45 to 55 μm, the sample was determined to be ×.

TABLE 2

| | | | | | | | Comparative | Comparative |
|---|---|---|---|---|---|---|---|---|
| | | Example 1 | Example 2 | Example 3 | Example 4 | Example 5 | Example 1 | Example 2 |
| Cured body | Resin sheet species | A | B | C | A | C | A | B |
| producing | Producing manner | Flat-plate | Flat-plate | Flat-plate | Compressive | Compressive | Flat-plate | Flat-plate |
| conditions | | manner | manner | manner | forming | forming | manner | manner |
| | Pressure (MPa) at stacked- | 2 | 8 | 2 | 1.5 | 1.5 | 0.5 | 1.5 |
| | body pressurizing time | | | | | | | |
| | Temperature (° C.) at stacked- | 90 | 90 | 90 | 150 | 150 | 90 | 90 |
| | body pressurizing time | | | | | | | |
| | Pressurizing period (min.) at | 5 | 5 | 5 | 30 | 5 | 5 | 5 |
| | stacked-body pressurizing time | | | | | | | |
| | Heating temperature (° C.) at | 150 | 150 | 150 | 150 | 150 | 150 | 150 |
| | sealed-body-resin-region | | | | | | | |
| | curing time | | | | | | | |
| | Heating period (hrs.) at | 1 | 1 | 1 | 1 | 1 | 1 | 1 |
| | sealed-body-resin-region | | | | | | | |
| | curing time | | | | | | | |
| Evaluations | Surface roughness (nm) | 320 | 1830 | 95 | 145 | 78 | 4530 | 3220 |
| | Light-exposure and development | ∘ | ∘ | ∘ | ∘ | ∘ | x | x |
| | (determination) | | | | | | | |

### DESCRIPTION OF REFERENCE SIGNS

1: Stacked body

11: Chip temporarily-fixed body

12: Thermosetting resin sheet

13: Separator

41: Lower heating plate

42: Upper heating plate

11a: Supporting plate

11b: Temporarily-fixing material

14: Semiconductor chip

14a: Electrode pad

51: Sealed body

52: Cured body

52A: Film-formation planning surface

61: Buffer coat film

61A and 61B: Openings

62: Mask

63: Resist

64: Plating pattern

65: Re-interconnection

66: Protective film

67: Electrode

68: Bump

69: Re-interconnection layer

53: Re-interconnection body

54: Semiconductor package

21: Cured resin

71: Through hole

72: Through electrode

75: Re-interconnection

77: Electrode

78: Bump

91: Light source

1. A semiconductor package producing method comprising:
a step of forming a sealed body by pressurizing a chip-temporarily-fixed body comprising a supporting plate, a temporarily-fixing material stacked over the supporting plate and a semiconductor chip fixed temporarily over the temporarily-fixing material, and a thermosetting resin sheet arranged over the chip temporarily-fixed body,
the sealed body comprising the semiconductor chip and the thermosetting resin sheet covering the semiconductor chip;
a step of forming a cured body by heating the sealed body to cure the thermosetting resin sheet,
the cured body comprising the semiconductor chip and the resultant cured resin covering the semiconductor chip;
a step of peeling off the temporarily-fixing material from the cured body; and
a step of forming a re-interconnection body by forming a re-interconnection layer over a surface of the cured body that had contacted the temporarily-fixing material;
wherein the step of forming the re-interconnection body comprises:
a step of forming a photosensitive buffer coat film over the surface of the cured body that had contacted the temporarily-fixing material, and
a step of making an opening in the buffer coat film by subjecting a workpiece to exposure to light and development; and
in the surface of the cured body that contacts the temporarily-fixing material, the cured resin has a surface roughness of 3000 nm or less.

2. The semiconductor package producing method according to claim 1, wherein in the step of forming the sealed body, the pressurizing is performed at a pressure of 1.0 MPa or more.

3. The semiconductor package producing method according to claim 1 or 2, further comprising:
a step of yielding semiconductor packages by making the re-interconnection body into individual pieces.

4. The semiconductor package producing method according to claim 2, further comprising:
a step of yielding semiconductor packages by making the re-interconnection body into individual pieces.
